(19) United States
(12) Patent Application Publication
(10) Pub. No.: US 2026/0323963 A1
(43) Pub. Date: Oct. 15, 2026

(54) ASSOCIATE PROCESSING UNIT TIGHTLY COUPLED TO HIGH BANDWIDTH MEMORY

(71) Applicant: GSI Technology Inc., Sunnyvale, CA (US)

(72) Inventors: Lee-Lean SHU, Los Altos, CA (US); Avidan AKERIB, Tel Aviv (IL); Bob HAIG, Austin, TX (US)

(21) Appl. No.: 19/717,748

(22) Filed: Jun. 24, 2026

Related U.S. Application Data
(63) Continuation of application No. 18/810,561, filed on Aug. 21, 2024.
(60) Provisional application No. 63/580,452, filed on Sep. 5, 2023.

(51) Int. Cl. H10B 80/00; H10W 90/00; H10W 90/20

(52) U.S. Cl. CPC H10B 80/00; H10W 90/00; H10W 90/297; H10W 90/722

(57) ABSTRACT

A semiconductor package assembly includes a package substrate, a processor, and a high bandwidth memory stack. The processor is mounted on the package substrate. The high bandwidth memory stack is vertically stacked with and mounted on the processor to form a compact three-dimensional integrated circuit structure. A plurality of memory layers within the high bandwidth memory stack interconnect vertically with one another via through-silicon vias. The through-silicon vias extend through the silicon substrates of the memory layers to electrically connect the high bandwidth memory stack directly to the processor. The processor has direct access to the entire high bandwidth memory stack. This direct access path allows the processor to retrieve data from any of the memory layers without routing signals through intermediate external controllers.

### CROSS REFERENCE TO RELATED APPLICATIONS

This application is a continuation application of U.S. Patent Application No. 18/810,561, filed Aug. 21, 2024 which claims priority from US provisional patent application 63/580,452 filed Sep. 5, 2023, both of which are incorporated herein by reference.

### FIELD OF THE INVENTION

The present invention relates generally to associative processing units and to associative processing units tightly coupled with high bandwidth memory in particular.

### BACKGROUND OF THE INVENTION

Multi-chip packaging technologies have emerged as a solution to address the increasing demands for higher performance and integration in electronic systems. One such technology is Chip-on-Wafer-on-Substrate (CoWoS), which incorporates multiple dies side-by-side on a silicon interposer. CoWoS facilitates the integration of various components, including high-bandwidth memory (HBM) and central processing units (CPUs) or graphics processing units (GPUs), onto a single package.

In a typical CoWoS configuration, as illustrated in FIGS. 1A and 1B, a silicon interposer serves as a connecting platform, enabling seamless connections and communication between various dies while effectively addressing pin-related challenges that arise due to differing pin counts among the various dies. FIG. 1A illustrates an exemplary Chip-on-Wafer-on-Substrate (CoWoS) 10. CoWos 10 is built on a package substrate 12 and includes a silicon interposer 14. At the center of CoWos 10 is a CPU (central processing unit) or a GPU (graphical processing unit) 20, which is surrounded by four HBM stacks 16, comprising multiple memory units 17 therein. Each HBM stack 16 is managed by an associated HBM stack controller 18.

FIG. 1B provides a cross-sectional view of CoWoS 10, showing how the dies of each stacked memory unit 16 are connected using through-silicon vias (TSVs) 22 and micro-bumps 24. TSVs 22 are vertical electrical connections that pass through silicon wafer or die, enabling different layers or components of a chip or stack to communicate vertically. Micro-bumps 24 are tiny solder bumps used to establish connections between different components within the three-dimensional integrated circuit. Dies are bonded to silicon interposer 14 using micro-bumps 24. Silicon interposer 14 is then thinned and bonded, via solder bumps 25, to package substrate 12.

HBM stack controller 18 communicates with memory units 17 in HBM stack 16 and with CPU/GPU die 20. This arrangement allows for high-bandwidth communication between memory and processing components while taking up less area on chip and providing higher bandwidth with less power consumption compared to traditional memory configurations. The development of such packaging technologies has enabled significant advancements in computing capabilities, particularly in applications requiring high memory bandwidth and processing power. These technologies continue to evolve to meet the growing demands of various industries, including artificial intelligence, data centers, and high-performance computing.

### SUMMARY OF THE PRESENT INVENTION

There is therefore provided, in accordance with a preferred embodiment of the present invention, a semiconductor package assembly. The assembly includes a package substrate, a processor mounted on the packages substrate, and a high bandwidth memory (HBM) stack vertically stacked with and mounted on the processor, where the HBM stack includes a plurality of memory layers that interconnect vertically via through-silicon vias (TSVs) that electrically connect the HBM stack to the processor, and the processor has direct access to the entire HBM stack.

Moreover, in accordance with a preferred embodiment of the present invention, the processor is mounted directly on the package substrate via solder bumps, and where the assembly is free of an intervening silicon interposer between the processor and the package substrate.

Further, in accordance with a preferred embodiment of the present invention, the assembly further includes a silicon interposer mounted on the package substrate, and the processor is mounted on and electrically connects to the silicon interposer.

Still further, in accordance with a preferred embodiment of the present invention, the processor is an associative processing unit (APU) including a memory array with rows and columns, the TSVs couple bit lines of the HBM stack to bit lines of the memory array, and the processor performs Boolean operations in parallel directly within the columns on data read from the HBM stack.

Additionally, in accordance with a preferred embodiment of the present invention, the processor serves as the primary processing unit for the entire assembly, eliminating the need for an external host central processing unit (CPU).

There is therefore provided, in accordance with a preferred embodiment of the present invention, a high bandwidth memory (HBM) device. The HBM device includes an HBM stack vertically stacked on the base logic die, the HBM stack includes a plurality of memory layers interconnected to the base logic die by through-silicon vias (TSVs). The base logic die includes an associative processing unit (APU) having a memory array with rows and columns and configured to perform operations directly within the memory array on data retrieved from the HBM stack, and the APU receives data directly from the HBM stack over the TSVs and returns computed results without transferring the data off the HBM device.

Moreover, in accordance with a preferred embodiment of the present invention, the APU serves as a primary processing unit for the HBM device and executes application workloads independently of an external host central processing unit (CPU).

Further, in accordance with a preferred embodiment of the present invention, the base logic die further includes an HBM physical layer (PHY) interface and an HBM stack.

Still further, in accordance with a preferred embodiment of the present invention, the APU performs a pattern search across data in the HBM stack directly within the memory array without reading the data out to an external host.

Additionally, in accordance with a preferred embodiment of the present invention, the base logic die further includes one or more embedded central processing unit (CPU) cores, a serial processor that couples thereto, and one or more direct memory access (DMA) engines that couple to the APU.

Moreover, in accordance with a preferred embodiment of the present invention, the base logic die further includes a local SRAM for temporary storage of data and a data buffer for managing data flow between the HBM stack and the APU.

Further, in accordance with a preferred embodiment of the present invention, the operations within the memory array include multiply-accumulate (MAC) operations or matrix operations.

Still further, in accordance with a preferred embodiment of the present invention, the APU performs Boolean operations.

Additionally, in accordance with a preferred embodiment of the present invention, the HBM device further includes a compute express link (CXL) interface over which intermediate results of computations return to an external host.

There is therefore provided, in accordance with a preferred embodiment of the present invention, a method for processing data in a high bandwidth memory (HBM) stack. The method includes storing data across the HBM stack, performing, by an associative processing unit (APU) integrated in a base logic die of the HBM stack, computations directly within a memory array on the data read from the HBM stack over through-silicon vias (TSVs), and returning computed results to an external host, where the computations execute within the HBM stack without transferring the data to the external host.

Moreover, in accordance with a preferred embodiment of the present invention, the computations include one or more of Boolean operations, matrix operations, multiply-accumulate (MAC) operations, or pattern searches.

Further, in accordance with a preferred embodiment of the present invention, the computations include executing a forward pass of a large language model (LLM) where portions of the LLM load into the HBM stack and the APU performs computations.

Still further, in accordance with a preferred embodiment of the present invention, the computations include a pattern search directly within the memory array on the data in the HBM stack.

Additionally, in accordance with a preferred embodiment of the present invention, the method further includes distributing processing of a LLM across multiple APUs that couple tightly to respective HBM stacks, where the multiple APUs interconnect via compute express link (CXL) interfaces.

Moreover, in accordance with a preferred embodiment of the present invention, the method further includes a switch fabric directing the data according to the computations.

Further, in accordance with a preferred embodiment of the present invention, layers of the LLM remain resident in the HBM stack across multiple forward passes, and where only input data and intermediate results traverse the TSVs between the HBM stack and the APU.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A is a schematic illustration of a prior art chip-on-wafer-on-substrate system;

FIG. 1B is a detailed schematic illustration of the prior art chip-on-wafer-on-substrate system of FIG. 1A;

FIG. 2 is a block diagram illustration of a prior art associative processing unit;

FIG. 3A is a schematic illustration of a chip-on-wafer-on-substrate assembly with a stack associative processing unit integrated with a high bandwidth memory stack, constructed and operative according to an embodiment of the present invention;

FIG. 3B is a detailed schematic illustration of the elements of the stack associative processing unit of FIG. 3A, constructed and operative according to an embodiment of the present invention;

FIG. 4 is a block diagram illustration of the integration elements of the stack associative processing unit, constructed and operative according to an embodiment of the present invention;

FIG. 5 is a schematic illustration of a chip-on-wafer-on-substrate system with multiple associative processing unit-high bandwidth memory stacks, constructed and operative according to an embodiment of the present invention;

FIG. 6 is a schematic illustration of a standalone associative processing unit-high bandwidth memory stack, constructed and operative according to an embodiment of the present invention;

FIG. 7 is a block diagram illustration of the standalone associative processing unit-high bandwidth memory stack of FIG. 6, constructed and operative according to an embodiment of the present invention; and

FIG. 8 is a schematic illustration of a multiple associative processing unit-high bandwidth memory system, constructed and operative according to an embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Applicant has realized that prior art systems utilizing Chip-on-Wafer-on-Substrate (CoWoS) technology with high-bandwidth memory (HBM) and central processing units (CPUs) or graphics processing units (GPUs) have limitations in terms of processing efficiency, power consumption, and space utilization.

Applicant has further realized that integrating a column parallel processor, such as the massively parallel, associative processing unit (APU), commercially available from GSI Technology Ltd of the USA, directly with an HBM stack, as part of a single semiconductor package assembly, may provide significant advantages over the prior art. This tight coupling of a parallel processing unit (i.e. the APU) to an HBM stack may result in a 3D stack package with a small footprint that provides massive parallel processing capabilities together with high capacity, high bandwidth memory.

Exemplary APUs are described in US patents, US 8,238,173, entitled “Using Storage Cells to Perform Computation”, US 9,418,719 entitled “In-Memory Computational Device”, and US 9,558,812, entitled “SRAM Multi-Cell Operations”, all assigned to the common assignee of the present invention and incorporated herein by reference.

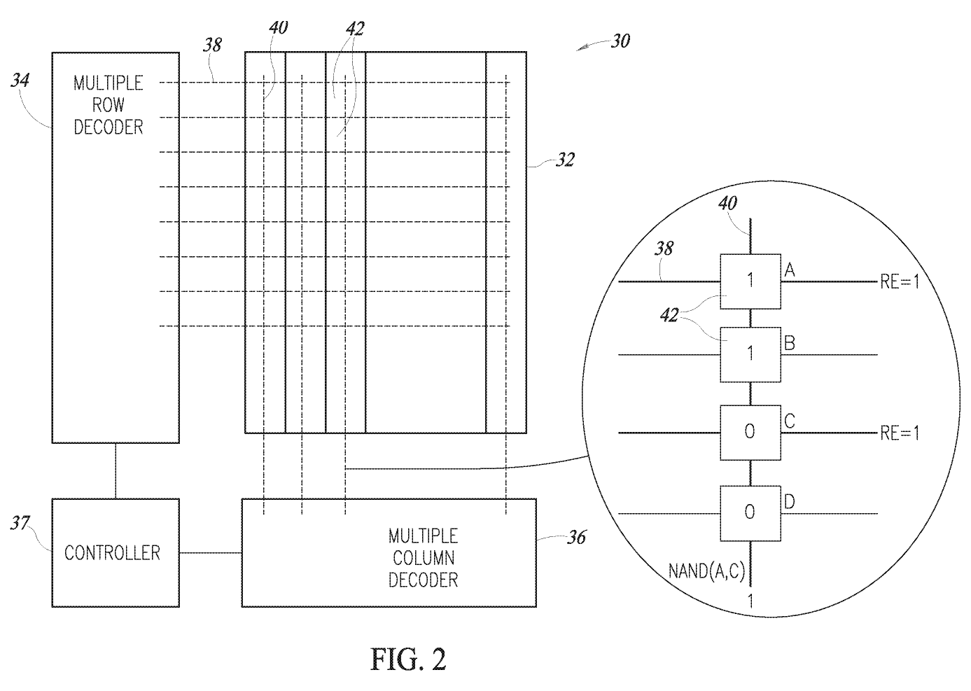

An exemplary APU is shown in FIG. 2, to which reference is now made, which illustrates a block diagram of an associative processing unit (APU) 30. APU 30 may comprise a memory array 32, a multiple row decoder 34, a multiple column decoder 36, and a controller 37. The memory array 32 may comprise a multiplicity of memory cells 42, connected together by word lines 38 and bit lines 40.

The controller 37 may control both multiple row decoder 34 and the multiple column decoder 36, coordinating their operations. Multiple row decoder 34 may be connected to and may activate multiple word lines 38, while multiple column decoder 36 may be connected to and may receive data from bit lines 40. In exemplary APU 30, data items are stored in columns. When a row is activated, the same bit from each column is activated. When multiple rows are activated at the same time, the same Boolean operation happens in each column, as described hereinbelow. In this way, the APU operates separately on each bit, on 32K values in parallel.

FIG. 2 includes an expanded view of an exemplary bit line 40, showing how bit lines 40 act as bit line processors when multiple rows are activated. The expanded view shows a series of memory cells 42, labeled A, B, C, and D. Cells 42 may be connected to multiple word lines 38 and one bit line 40. In the example shown in FIG. 2, the values stored in cells A, B, C, and D are 1, 1, 0, and 0 respectively. When the word lines 38 receive an active read enable (RE), they activate the rows of cells A and C and the output on bit line 40 performs a Boolean operation (in this case, a NAND) between cells A and C, generating a 1, as shown.

Note that the same operation may be performed in each bit line, in parallel. Thus, any Boolean operation or series of Boolean operations may be performed in parallel directly within memory array 32.

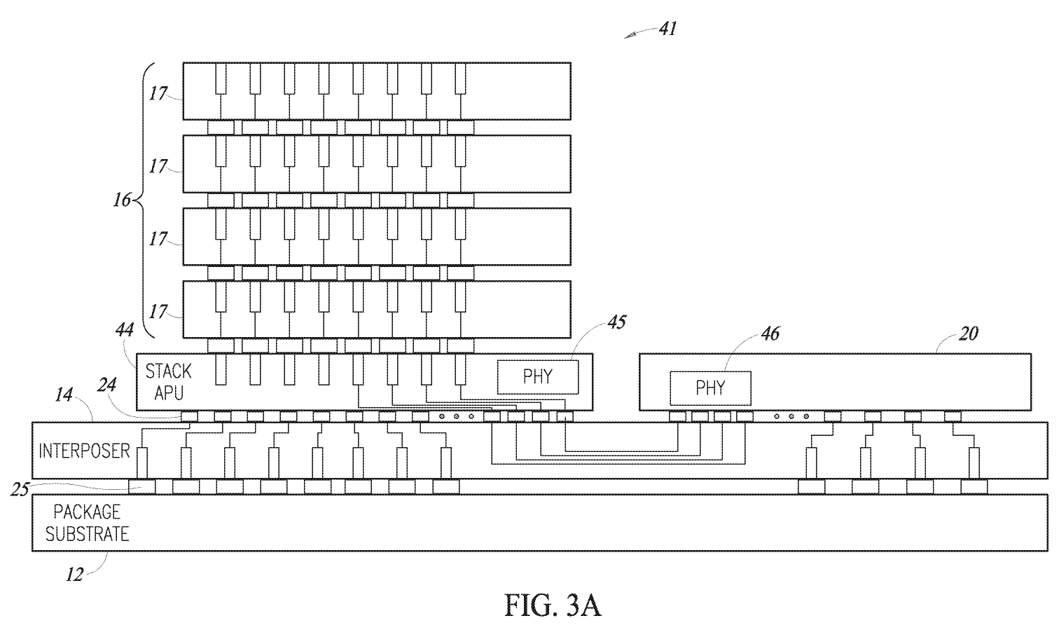

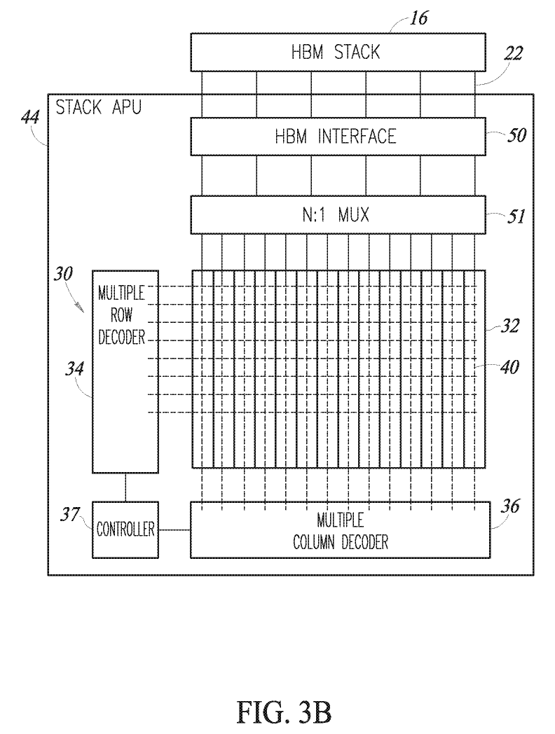

Reference is now made to FIG. 3A, which illustrates a cross-sectional view of an exemplary embodiment of an APU-HBM 41 of the present invention, and to FIG. 3B, which illustrates the stack elements of APU-HBM 41. In this embodiment, a stack APU, here labeled 44, may be tightly coupled with an HBM stack 16 in a Chip-on-Wafer-on-Substrate (CoWoS) configuration.

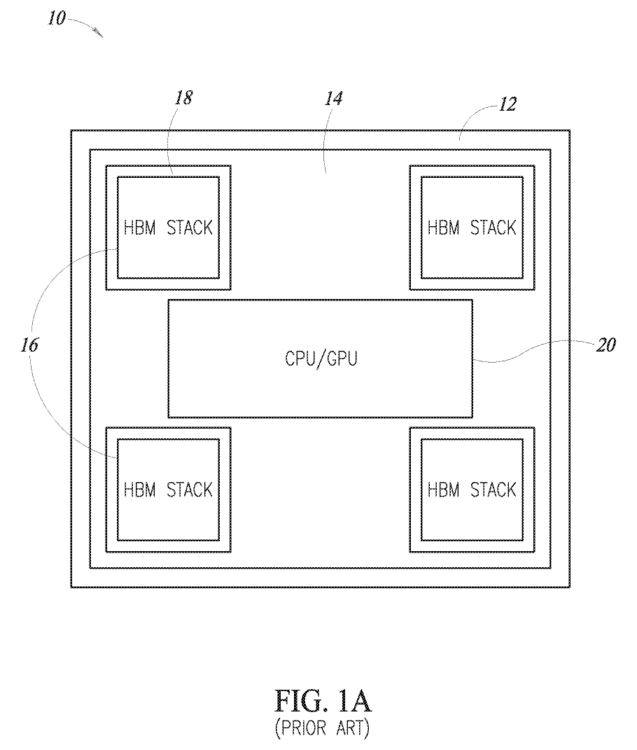

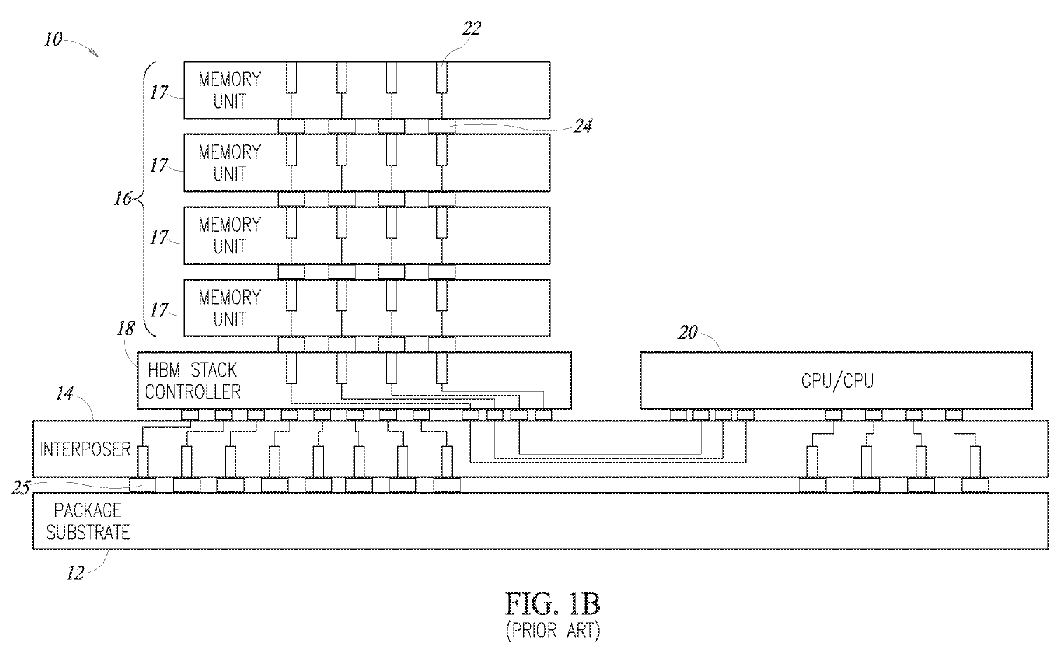

The structure is built on a package substrate 12, similar to the CoWoS 10 shown in FIG. 1B. As in FIG. 1B, a silicon interposer 14 is mounted on the package substrate 12, serving as a connecting platform for the various components.

In this embodiment, stack APU 44 is positioned directly beneath HBM stack 16, which, as in FIGS. 1A and 1B, comprises multiple stacked memory units 17. Stack APU 44 may include a physical (PHY) interface 45 for communication with other components. As in FIGS. 1A and 1B, HBM stack 16 is connected together using TSVs 22, which enable vertical electrical connections among the memory layers and, in this embodiment, to stack APU 44 as well. In this embodiment, HBM stack 16 may be any type of HBM stack, such as a 3D DRAM stack, a non-volatile 3D stack, formed of SSD memory, or any 3D storage technology stack. Memory array 32 of stack APU 44 may be any suitable memory array, such as anon-volatile memory array and/or an SRAM memory array.

It will be appreciated that stack APU 44, in addition to providing parallel processing capabilities as discussed hereinbelow, may also replace HBM stack controller 18, which was a separate component in the prior art. It will further be appreciated that stack APU 44 may provide more efficient management of HBM stack 16, as a result of the tighter coupling between stack APU 44 and HBM stack 16. A separate die containing a CPU, GPU, or System-on-Chip (SoC) 20 may also be positioned on interposer 14. This processor die 20 may also include a CPU PHY interface 46 for communication with other components.

Microbumps 24 are used to connect the various components to the interposer 14 and to each other, facilitating high-speed, short-distance communication between the elements.

FIG. 3B is a schematic illustration of some of the elements of stack APU 44 connected to HBM stack 16. HBM stack 16 may be tightly coupled to stack APU 44 via TSVs 22. Stack APU 44 may also include an HBM interface 50 that communicates with the HBM stack through TSVs 22 and an N:1 multiplexer (MUX) 51 to provide a wide bus to interface to HBM stack 16, due to the very high signal rate of HBM stack 16. An exemplary N:1 MUX 51 may be a 4:1 MUX, meaning that, each bit line of HBM stack 16 feeds 4 bit lines of memory array 32 of APU 30.

For example, HBM interface 50 may generate 2K signals at 9.6Gbps/pin. From this, N:1 MUX 51 may generate 8K signals at a speed of at least 2.4 Gbps/signal. Typically, the bandwidth of memory array 32 may be greater than or equal to the bandwidth of HBM interface 50.

N:1 MUX 51 may be connected to bit lines 40 of APU 30. This interconnection of bit lines from HBM stack 16, through N:1 MUX 51, to bit lines 40 may enable reading directly from the HBM bit lines to APU bit lines 40. Multiple read operations from memory cells 42 in stack APU 44 may generate NOR, OR, or other logical operations and may produce Boolean operations on the data in memory cells 42. The results may be written back to cells in HBM stack 16.

It will be appreciated that, due to the direct reading from HBM memory units 17 to stack APU 44 and due to the reduced distance therebetween, stack APU 44 may provide more efficient data processing. The integration of stack APU 44 with HBM stack 16 may also result in a smaller overall footprint, potentially freeing up space on interposer 14 for additional components or larger memory capacity.

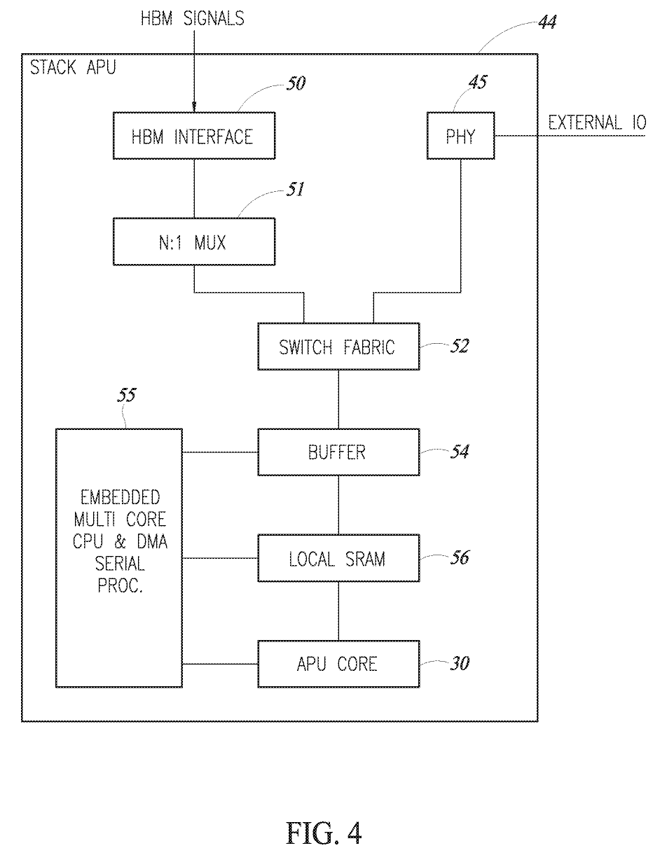

Reference is now made to FIG. 4, which is a detailed block diagram of stack APU 44. In this embodiment, stack APU 44 may include HBM interface50, together with its N:1 MUX51, a switch fabric 52, a PHY interface 45 to an external input/output (IO) unit, a buffer 54, a local SRAM 56, APU 30 (here labeled ‘APU core’), and a serial processor 55 for embedded multi-core CPUs and DMAs (direct memory access devices). HBM interface 50 may connect bit lines from HBM stack 16 to switch fabric 52 throughN:1 MUX51.

Switch fabric 52 may manage data routing within stack APU 44 and may also be connected to APU core 30 and local SRAM 56 through buffer 54, thereby to provide the signals from HBM stack 16 to APU core 30. Switch fabric 52 may also provide output to external IO through PHY 45. Thus, to output HBM signals, the HBM signals may pass through HBM interface 50 and N:1 MUX51to switch fabric 52 and from there, through PHY45 to the external IO unit.

Given that HBM memory units 17 and the external IO unit may not be synchronized with APU core 30 and local SRAM 56, buffer 54 may serve as a temporary storage for such data and, to that end, buffer 54 may be connected to switch fabric 52.

Local SRAM 56 may be a local memory storage unit tightly coupled to APU core 30, to store data currently being processed. Local SRAM 56 may be connected to multiple elements, to buffer 54, to serial processor 55 and to APU 30.

Since the data from HBM memories 17 may flow to stack APU 44, stack APU 44 comprises serial processor 55, which may provide the data from HBM memories 17 to GPU/CPU 20, typically via DMAs. Serial processor 55 may comprise an ALU (arithmetic logic unit), a data and instruction storage unit, a fast access memory or DMA (direct memory access) to load data and instructions from external memory to CPU/GPU 20, independently of the CPU.

Thus, data may be provided both to CPU/GPU 20 and to APU 30 for processing. Switch fabric 52 may be responsible for directing the data according to the type of processing to be performed.

It will be appreciated that prior art HBMs can only work with an external host CPU (i.e. external toCoWoS10 via CoWoS interposer 14, because the external host CPU cannot handle the amount of data the prior art HBMs provide all at once. As a result, HBM memory cannot replace the internal host device memory. It will be appreciated that APU-HBM 41, which can operate at the HBM data rate, may be able to process some of the HBM data for the external host CPU.

In an alternative embodiment, adding an advanced controller, such as an ARM (Advanced RISC Machine) core, an ARC or a RISC 5 controller, to an APU-HBM stack (i.e. stack APU 44 with HBM stack 16), may enable the external host CPU to communicate at the HBM data rate.

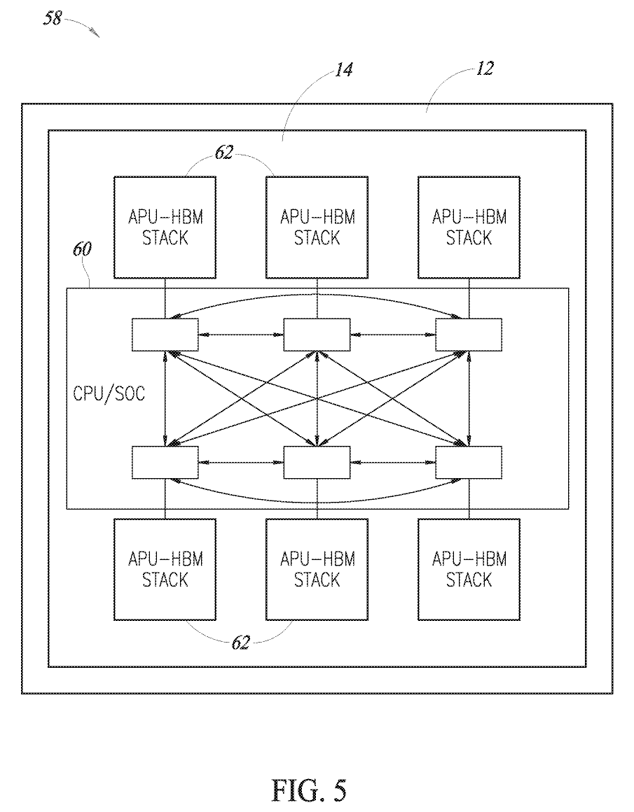

Applicant has realized that, when stack APU 44 may be installed in a CoWoS package, which facilitates the integration of various components placed on silicon interposer 14, there may be no need for a GPU type of processing unit. Moreover, a CPU/SOC (system on a chip) may serve as a switch to interconnect APU-HBM components, rather than as a processing unit. Such an APU-HBM CoWos system 58 is shown in FIG. 5, to which reference is now made.

APU-HBM CoWoS system 58 may comprise multiple APU-HBM stacks 62 (i.e. stack APU 44 with HBM stack 16) arranged in a grid-like configuration on interposer 14. In the exemplary embodiment of FIG. 5, six APU-HBM stacks 62 may be positioned in a 2x3 arrangement, surrounding a central CPU/SOC 60.

CPU/SOC 60 may be connected to each of the surrounding APU-HBM stacks 62, forming a network of interconnections. These connections may enable communication and data transfer between the CPU/SOC 60 and the APU-HBM stacks 62. The layout of APU-HBM CoWoS system 58 on interposer 14, with stacks 62 surrounding central CPU/SOC 60, may allow for high-bandwidth communication between the APU-HBM stacks 62 and the central CPU/SOC 60.

The APU-HBM stacks 62 may also be interconnected with each other, allowing for direct communication between adjacent units. This all-to-all interconnected structure may facilitate efficient data sharing and processing across the entire APU-HBM CoWoS system 58. Other interconnections might be ring connections, star connections, etc.

Since APU-HBM CoWoS system 58 has only APU-HBM stacks 62 and no other type of processor, the data rate may be high through interposer 14. For example, at current CoWoS operation rates, system 58 may have a 7.2TB (terabyte)/sec data rate.

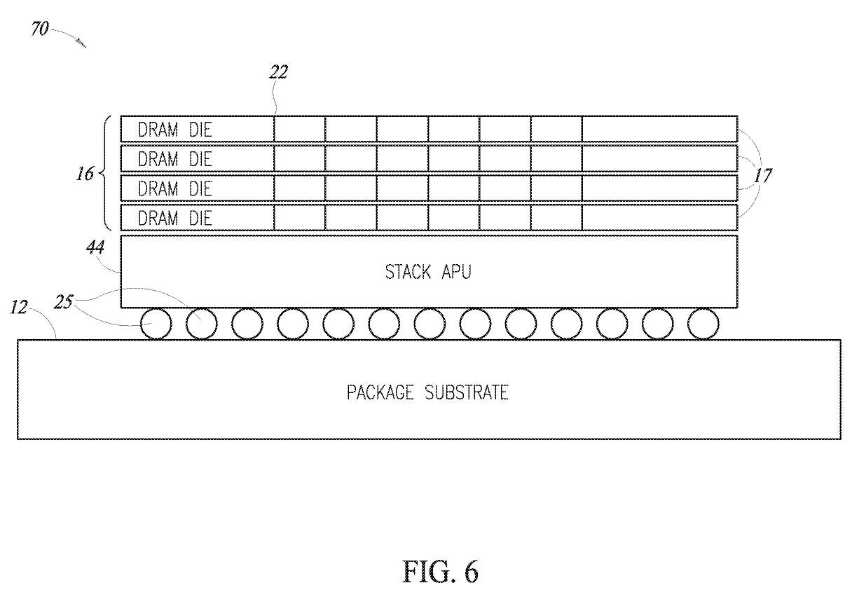

Applicant has further realized that, with stack APU 44 as part of the HBM stack, the GPU or CPU in a traditional CoWoS package may be unnecessary. The freed space may be utilized to accommodate additional HBM stacks, thereby increasing storage capacity and bandwidth while lowering power consumption due to the computation being performed on the APUs attached directly to the HBM. This standalone APU-HBM 70 is shown in a cross-sectional view in FIG. 6, to which reference is now made.

In this embodiment, the standalone APU-HBM 70 may be built on package substrate 12, similar to the previously described configurations. However, unlike the prior embodiments, standalone APU-HBM 70 may not include a separate CPU or GPU component.

The standalone APU-HBM 70 may comprise stack APU, here labeled 44’,positioned directly on package substrate 12, connected via solder bumps 25. Stack APU 44’may serve as the primary processing unit for the entire assembly, eliminating the need for a separate CPU or GPU.

Stacked above stack APU 44’ may be HBM stack 16, which may consist of multiple layers of memory units 17. These memory units 17 may be interconnected and connected to stack APU 44’ through TSVs 22, enabling high-bandwidth vertical communication within the stack.

By integrating stack APU 44’directly with HBM stack 16 and eliminating the separate CPU/GPU component, standalone APU-HBM 70 may achieve a more compact and efficient design. This configuration may allow for increased storage capacity and bandwidth within the same or smaller footprint compared to traditional CoWoS packages. This standalone APU-HBM 70 configuration may be particularly advantageous for data center and/or Internet edge applications.

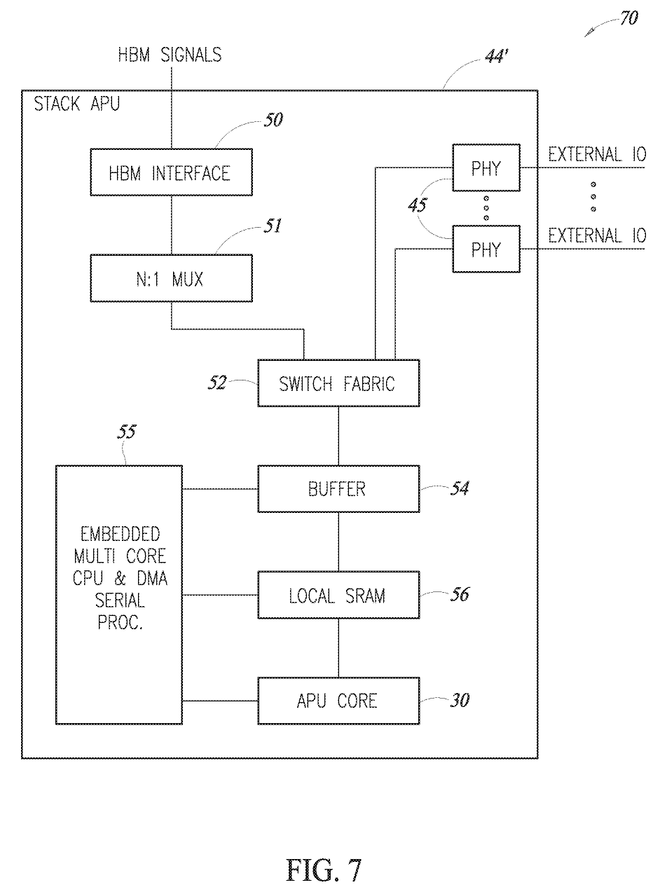

FIG. 7, to which reference is now made, illustrates a detailed block diagram of standalone APU-HBM 70. The elements are similar to those in FIG. 4, except that, in this embodiment, standalone APU-HBM 70 may comprise a single HBM interface 50 and multiple PHY interfaces, for example, for communicating with multiple standalone APU-HBMs 70, or external host CPUs, such as exist in data centers. As for the previous embodiments, standalone APU-HBM 70 also comprises switch fabric 52, buffer 54, local SRAM 56, APUcore30 and serial processor 55.

Serial processor 55 may comprise the elements needed to communicate with a CPU, GPU, SOC, etc.; however, in this standalone embodiment, the processing unit is external to standalone APU-HBM 70.

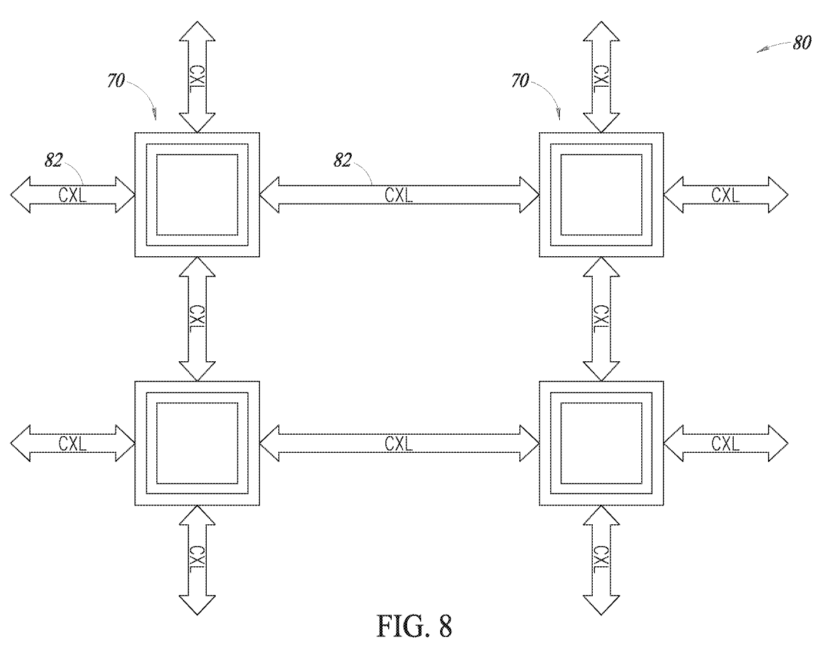

Reference is now made to FIG. 8, which illustrates a multiple APU-HBM based system 80. In this embodiment, system 80 may comprise multiple standalone APU-HBM units 70 interconnected through CXL (Compute Express Link) links 82. The CXL links 82 may provide high-bandwidth, low-latency connections between the APU-HBM units 70, increasing the speed of data transfer and communication within the system.

System 80 may be arranged in a grid-like configuration on a card, with each APU-HBM unit 70 connected to its adjacent units via CXL links 82. This interconnected structure may allow for direct communication between neighboring APU-HBM units 70, potentially reducing data transfer times and improving overall system performance, even over the CoWoS systems described hereinabove. Importantly, this embodiment is not dependent on the size of a CoWoS chip.

In addition to the internal connections, each APU-HBM unit 70 in system 80 may also have external CXL links 82 extending outwards. These external links may enable communication with other systems or components outside of the immediate grid, providing flexibility for scaling and integration into larger computing environments.

Large Language Models (LLMs), such as Chat-GPT in generative AI, is one of the key technologies of interest nowadays. LLMs process vast amounts of text data. The vast amount of data may be distributed among the many HBMs in the system. As a result, a major issue in LLM implementation is the link speed among HBMs. The latency and power consumption needed to transfer the data between HBMs may be reduced with the systems of the present invention, which directly connect between the HBM and the APU bit lines.

In an exemplary application, any of the APU-HBM systems, such as APU-HBM 41, APU-HBM CoWos system 58, standalone APU-HBM 70, or system 80, may be utilized to process large language models (LLMs). For example, standalone APU-HBM 70 may load an LLM into HBM stack 16, with different layers of the model distributed across multiple memory units 17. Stack APU 44 may then perform various operations on the model data.

For instance, standalone APU-HBM 70 may execute a forward pass through the LLM. In this process, input data may be provided to the first layer of the model stored in HBM stack 16. Stack APU 44 may read this data directly from HBM stack 16 via TSVs 22 and HBM interface 50. APU core 30 within stack APU 44 may then perform matrix multiplications and other necessary computations for each layer of the model. Local SRAM 56 may store a large matrix or may be used as a cache memory for the key-value calculations of SoftMax. Local SRAM 56 may provide a large cache on stack APU 44, thereby reducing the number of transactions with HBM stack 16.

Data from HBM stack 16 goes to local SRAM 56 via HBM interface 50 and switch fabric 52. Stack APU 44 and controller 37 process all LLM flows while keeping intermediate results inside local SRAM 56.

As the forward pass progresses, intermediate results may be temporarily stored in local SRAM 56 for quick access. Buffer 54 may be used to manage the flow of data between HBM stack 16 and the processing elements. Switch fabric 52 may route data and results between different components of standalone APU-HBM 70 as needed. Output may be provided to an external host computer through PHY interface 45.

For larger models that exceed the capacity of a single APU-HBM unit, processing may be distributed across multiple units in system 80 of FIG. 8. In this case, different layers or portions of the model may be stored in separate standalone APU-HBM units 70. CXL links 82 may facilitate the transfer of intermediate results between units as the forward pass progresses through the model.

System 80 may also support parallel processing of multiple inputs or batches. In this scenario, different standalone APU-HBM units 70 may process separate inputs simultaneously, leveraging the high bandwidth and low latency of CXL links 82 to share results or synchronize operations as necessary.

In an exemplary search operation, the APU-HBM system may perform a search for a specific pattern within a large dataset stored in the HBM stack. A host computer may provide a search query to the APU-HBM system, such as standalone APU-HBM 70. Stack APU 44 may load the data to be searched into local SRAM 56.

APU core 30 may then perform a parallel comparison of the search pattern against all data in its memory array 32. The results of this parallel comparison may be stored in a result vector within memory array 32. Stack APU 44 may then read this result vector to identify matching patterns. If matches are found, stack APU 44 may provide the results as output or as an interim result.

For large datasets that exceed the capacity of local SRAM 56, stack APU 44 may divide the search operation into multiple stages. In each stage, a portion of data from HBM stack 16 may be loaded into local SRAM 56, searched, and then replaced with the next portion of data.

Throughout this process, switch fabric 52 may manage data flow between HBM interface 50, local SRAM 56, and APU 30. Buffer 54 may be used to temporarily store intermediate results or data being transferred between components.

If the search operation requires additional processing, such as ranking or filtering results, stack APU 44 may utilize its parallel processing capabilities to perform these tasks efficiently. Final search results may be sent to an external host computer via PHY interface 45.

In cases where the dataset is distributed across multiple standalone APU-HBM units 70 in system 80, each unit may perform the search operation on its local data. Results from individual units may then be aggregated using CXL links 82, with one unit designated as the master to compile and process the final results.

A pipeline generative AI (GAI) embodiment may utilize multiple standalone APU-HBM units 70 in system 80, where each standalone APU-HBM unit 70 may have a specific set of storage parameters. Once each standalone APU-HBM unit 70 has finished its computation, it pipelines its result to a next stage implemented by a next standalone APU-HBM unit 70.

In addition to the embodiments disclosed herein, the present invention may be implemented for the following types of operations: pattern searches, AI, neural network processing, large language models (LLMs), Boolean (bit-by-bit) operations, MAC (multiply-accumulate), matrix operations, etc., CAM/TCAMs, SQL databases, cyber security, cryptography, encryption and decryption, password recovery, blockchain, Computer vision, big data, and semantic searches.

APU-HBM 41, and the other APU-HBM systems described herein, may offer several advantages over traditional computing architectures. By tightly coupling stack APU 44 with HBM stack 16, APU-HBM 41 may significantly reduce data movement between processing and memory units. This reduction in data movement may lead to lower power consumption and improved energy efficiency. The close proximity of stack APU 44 to HBM stack 16 may also result in reduced latency, as data can be accessed and processed more quickly.

APU-HBM 41, and the other APU-HBM systems described herein, may provide enhanced parallelism capabilities. Stack APU 44 may perform massive parallel operations, in-memory, on data stored in HBM stack 16, potentially accelerating computations for applications such as machine learning, data analytics, and scientific simulations. This parallel processing capability may be particularly beneficial for handling large datasets and complex algorithms.

The integration of stack APU 44 with HBM stack 16 in standalone APU-HBM 70 may allow for a more compact and space-efficient design compared to traditional architectures. This integration may result in a smaller overall footprint, potentially enabling higher density computing solutions in data centers and other space-constrained environments.

Standalone APU-HBM 70 may offer improved scalability. Multiple standalone APU-HBM 70 units can be interconnected, as demonstrated in system 80, allowing for the creation of larger, more powerful computing systems. This scalability may be particularly advantageous for handling increasingly complex and data-intensive workloads.

The architecture of standalone APU-HBM 70 may provide greater flexibility in terms of memory allocation and utilization. Stack APU 44 may have direct access to the entire HBM stack 16, potentially allowing for more efficient memory management and utilization compared to traditional cache-based architectures.

It will be appreciated that standalone APU-HBM 70 may be installed in other architectures as well, such as on CPU motherboards and/or in data centers. As described hereinabove, standalone APU-HBM 70 renders CPU/GPU 20 redundant, thereby expanding the storage capacity on the same die size.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A semiconductor package assembly comprising:
a package substrate;
a processor mounted on said package substrate; and
a high bandwidth memory (HBM) stack vertically stacked with and mounted on said processor, said HBM stack comprising a plurality of memory layers interconnected vertically via through-silicon vias (TSVs) that electrically connect said HBM stack to said processor;
wherein said processor has direct access to said entire HBM stack.

2. The assembly according to claim 1, wherein said processor is mounted directly on said package substrate via solder bumps, and wherein said assembly is free of an intervening silicon interposer between said processor and said package substrate.

3. The assembly according to claim 1, further comprising a silicon interposer mounted on said package substrate, wherein said processor is mounted on and electrically connected to said silicon interposer.

4. The assembly according to claim 1, wherein said processor is an associative processing unit (APU) comprising a memory array with rows and columns, wherein said TSVs couple bit lines of said HBM stack to bit lines of said memory array, and wherein said processor is configured to perform Boolean operations in parallel directly within said columns on data read from said HBM stack.

5. The assembly according to claim 1, wherein said processor serves as the primary processing unit for said entire assembly, eliminating the need for an external host central processing unit (CPU).

6. A high bandwidth memory (HBM) device comprising:
a base logic die; and
an HBM stack vertically stacked on said base logic die, said HBM stack comprising a plurality of memory layers interconnected to said base logic die by through-silicon vias (TSVs);
wherein said base logic die comprises an associative processing unit (APU) having a memory array with rows and columns and configured to perform operations directly within said memory array on data retrieved from said HBM stack; and
wherein said APU receives data directly from said HBM stack over said TSVs and returns computed results without transferring said data off said HBM device.

7. The HBM device according to claim 6, wherein said APU serves as a primary processing unit for said HBM device and is configured to execute application workloads independently of an external host central processing unit (CPU).

8. The HBM device according to claim 6, wherein said base logic die further comprises an HBM physical layer (PHY) interface and an HBM stack.

9. The HBM device according to claim 6, wherein said APU is configured to perform a pattern search across data stored in said HBM stack directly within said memory array without reading said data out to an external host.

10. The HBM device according to claim 6, wherein said base logic die further comprises one or more embedded central processing unit (CPU) cores, a serial processor coupled thereto, and one or more direct memory access (DMA) engines coupled to said APU.

11. The HBM device according to claim 6, wherein said base logic die further comprises a local SRAM for temporary storage of data and a data buffer for managing data flow between said HBM stack and said APU.

12. The HBM device according to claim 6, wherein said operations performed directly within said memory array include multiply-accumulate (MAC) operations or matrix operations.

13. The HBM device according to claim 6, wherein said APU is configured to perform Boolean operations.

14. The HBM device according to claim 6, further comprising a compute express link (CXL) interface over which intermediate results of computations are returned to an external host.

15. A method for processing data in a high bandwidth memory (HBM) stack, the method comprising:
storing data across said HBM stack;
performing, by an associative processing unit (APU) integrated in a base logic die of said HBM stack, computations directly within a memory array on said data read from said HBM stack over through-silicon vias (TSVs); and
returning computed results to an external host;
wherein said computations are processed within said HBM stack without transferring said data to said external host.

16. The method of claim 15, wherein said computations comprise one or more of: Boolean operations, matrix operations, multiply-accumulate (MAC) operations, or pattern searches.

17. The method of claim 15, wherein said computations comprise executing a forward pass of a large language model (LLM) where portions of said LLM are loaded into said HBM stack and computations are performed by said APU.

18. The method of claim 15, wherein said computations comprise a pattern search directly within said memory array on said data stored in said HBM stack.

19. The method of claim 17, further comprising distributing processing of a large language model (LLM) across multiple APUs tightly coupled to respective HBM stacks, wherein said multiple APUs are interconnected via compute express link (CXL) interfaces.

20. The method of claim 15, further comprising directing said data by a switch fabric according to said computations.

21. The method of claim 15, wherein layers of said LLM remain resident in said HBM stack across multiple forward passes, and wherein only input data and intermediate results traverse said TSVs between said HBM stack and said APU.
